(19) United States
(12) Patent Application Publication
(10) Pub. No.: US 2025/0068552 A1
(43) Pub. Date: Feb. 27, 2025

(54) MEMORY DEVICE FOR CONTROLLING ASYNCHRONOUS FIFO MEMORY WITH ASYMMETRIC DATA WIDTH

(71) Applicant: Alpha Solutions, Inc., Seongnam-si (KR)

(72) Inventors: Sungoo HWANG, Cheongju-si (KR); Ook KIM, Jongno-gu (KR)

(21) Appl. No.: 18/813,756

(22) Filed: Aug. 23, 2024

(30) Foreign Application Priority Data
Aug. 25, 2023 (KR) 10-2023-0112093

(51) Int. Cl. G06F 12/02

(52) U.S. Cl. CPC G06F 12/0223

(57) ABSTRACT

A memory device for controlling an asynchronous FIFO memory of an asymmetric data width is disclosed. A memory device according to one embodiment includes a First-in, First-out (FIFO) memory where data is input and output, an address counter that controls writing and reading of the FIFO memory, an address pointer generator that is capable of comparing a write clock domain and a read clock domain for checking a status of the FIFO memory, and a flag generator that outputs the status of the FIFO memory based on a comparison of address pointers generated by the address pointer generator, wherein a write data width and a read data width are differently processed in the FIFO memory.

### CROSS-REFERENCE TO RELATED APPLICATION

Pursuant to 35 U.S.C. § 119(a), this application claims the benefit of the earlier filing date and the right of priority to Korean Patent Application No. 10-2023-0112093, filed on Aug. 25, 2023, the contents of which are incorporated by reference herein in their entirety.

### BACKGROUND

### Field

The present disclosure relates to a memory device for controlling an asynchronous FIFO memory with an asymmetric data width.

### Description of the Related Art

Video transmitter/receiver devices use a high-speed interface technology, and the relationship between video streams and high-speed streams is different not only in clocks but also in data widths transmitted per clock. That is, a device is needed that converts a width of data as well as a clock between clock domains.

FIG. 1 is a block diagram illustrating conversion of clocks and data widths in a DisplayPort transmitter device that complies with a high-speed interface standard for video streams.

The video stream input and high-speed serial interface output of the device each support a variety of data widths and clock frequencies, depending on corresponding standards.

Video data has input data width and clock determined depending on resolution, and data width and clock of a high-speed interface for video transmission are transmitted with a bandwidth equal to or greater than that of a video stream.

In the related art transmitter/receiver devices, there was a problem in that a separate data width conversion circuit had be configured, even though FIFO for clock conversion had a sufficient memory capacity, due to the limitation that the FIFO had the same data width for input and output.

FIG. 2 is a schematic diagram of the related art asynchronous FIFO memory.

The related art asynchronous FIFO memory 200 has the same write data width and read data width, and includes address pointers 210w and 210r for comparing data between write and read clocks and a comparator. The unit of the address pointers corresponds to a data width since the read data width and the write data width are the same.

The related art asynchronous FIFO memory, although not illustrated in FIG. 2, has a problem that a separate data width conversion circuit is required and occupies a large area.

### SUMMARY

One aspect of the present disclosure to solve those problems mentioned above is to provide a memory device for controlling an asynchronous FIFO memory with an asymmetric data width, in which data width can be converted.

The tasks to be solved in the present disclosure may not be limited to the aforementioned, and other problems to be solved by the present disclosure will be obviously understood by a person skilled in the art based on the following description.

According to one embodiment of the present disclosure for solving the above-described problems, there is provided a memory device including a First-in, First-out (FIFO) memory where data is input and output, an address counter that controls writing and reading of the FIFO memory, an address pointer generator that is capable of comparing a write clock domain and a read clock domain for checking a status of the FIFO memory, and a flag generator that outputs the status of the FIFO memory based on a comparison of address pointers generated by the address pointer generator, wherein a write data width and a read data width are differently processed in the FIFO memory.

In an embodiment, the FIFO memory may include a first clock domain in which write data is processed and a second clock domain in which read data is processed, and may be an asymmetric FIFO memory in which the write data width processed in the first clock domain and the read data width processed in the second clock domain are different from each other.

In an embodiment, the FIFO memory may include a write address decoder and a read address decoder, the write address decoder may be configured with the write data width, and the read address decoder may be configured with the read data width.

In an embodiment, the address pointer generator may generate the address pointers in unit of greatest common divisor of the write data width and the read data width to compare address pointers between a first clock domain where write data is processed and a second clock domain where read data is processed.

In an embodiment, the address counter may count a data width of each of a first clock domain where write data is processed and a second clock domain where read data is processed, which are included in the FIFO memory, the address pointer generator may generate the address pointers in unit of greatest common divisor of the write data width and the read data width to compare the address pointers between the first clock domain and the second clock domain, and the flag generator may include a comparator that compares the address pointer of the first clock domain with the address pointer of the second clock domain.

In an embodiment, the address pointer generator may increase a write address pointer by a value obtained by dividing the write data width by the greatest common divisor of the write data width and the read data width, and increase a read address pointer by a value obtained by dividing the read data width by the greatest common divisor.

In an embodiment, the flag generator may output a flag regarding the status of the FIFO memory based on a result of comparing the address pointer of the first clock domain with the address pointer of the second clock domain in the comparator.

In an embodiment, the address counter may be driven in unit of the write data width and the read data width, and the address pointer generator and the flag generator may be driven in the unit of the greatest common divisor of the write data width and the read data width.

In an embodiment, the write data width and the read data width may be changed depending on settings.

Besides, other methods for implementing the present disclosure, other systems, and computer-readable recording media recording a computer program for executing the method may be further provided.

According to the present disclosure as described above, a data width conversion function can further be applied to the related art FIFO memory for clock conversion, resulting in implementing a circuit with a smaller area than that of the related art by using a clock conversion memory upon a data width conversion.

The effects of the present disclosure are not limited to those effects mentioned above, and other effects not mentioned may be clearly understood by those skilled in the art from the following description.

### BRIEF DESCRIPTION OF THE DRAWINGS

FIG. 1 is a block diagram illustrating the conversion of clock and data width of DisplayPort, which is a high-speed interface for video transmission that requires various conversions of data widths and clocks.

FIG. 2 is a block diagram of the related art asynchronous FIFO memory.

FIG. 3 is an overall block diagram illustrating an asymmetric asynchronous FIFO memory device according to the present disclosure.

FIG. 4 is a block diagram of an asymmetric memory with different write and read data widths.

FIG. 5 is a block diagram illustrating an address counter in unit of each data width, an address pointer in unit of greatest common divisor of write and read data widths, and a comparator.

FIG. 6 is a block diagram of status flag calculation using comparison of address pointers in unit of greatest common divisor of write and read data widths.

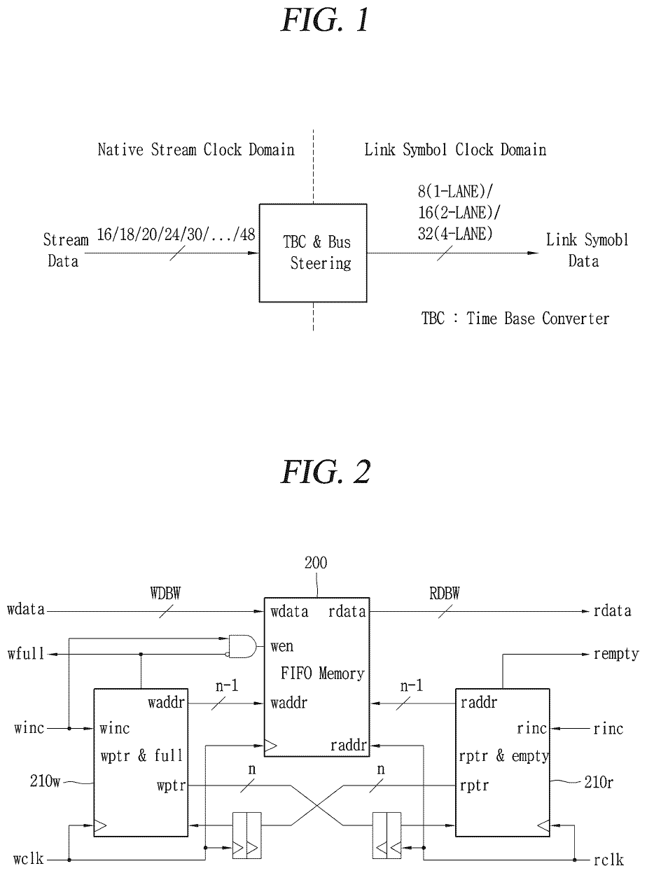

### DETAILED DESCRIPTION OF THE EMBODIMENTS

The advantages and features of the present disclosure and methods for achieving them will become apparent with reference to the embodiments to be described in detail below together with the accompanying drawings. However, the present disclosure is not limited to the embodiments disclosed below, but can be implemented in various different forms, the embodiments are provided only to make the present disclosure complete and to fully inform the scope of the present disclosure to a person skilled in the art, to which the present disclosure pertains, and the present disclosure is defined only by the scope of the claims.

The terminology used herein is for the purpose of describing the embodiments only and is not intended to limit the disclosure. The expression in the singular form in this specification will cover the expression in the plural form unless otherwise indicated obviously from the context. The terms “comprises” and/or “comprising” as used in the specification do not exclude the presence or addition of one or more other components in addition to components disclosed. The same/like reference numerals throughout the specification refer to the same/like components, and the term “and/or” includes each of the components disclosed and one or every combination of one or more of the components. Although “first”, “second”, etc. are used to describe various components, these components are not limited by these terms. These terms are only used to distinguish one component from another. Therefore, it goes without saying that a first component mentioned below may also be a second component within the technical concept of the present disclosure.

Unless otherwise defined, all terms (including technical and scientific terms) used herein may be used in a meaning that is commonly understood by a person skilled in the art to which the present disclosure pertains. Additionally, terms defined in commonly used dictionaries are not to be interpreted ideally or excessively unless explicitly and specifically defined otherwise.

Hereinafter, embodiments of the present disclosure will be described in detail with reference to the attached drawings.

Before the explanation, the meaning of terms used in this specification is briefly explained. However, since the explanation of terms is intended to help understanding of this specification, it should be noted that they are not used to limit the technical idea of the present disclosure unless explicitly stated to limit the present disclosure.

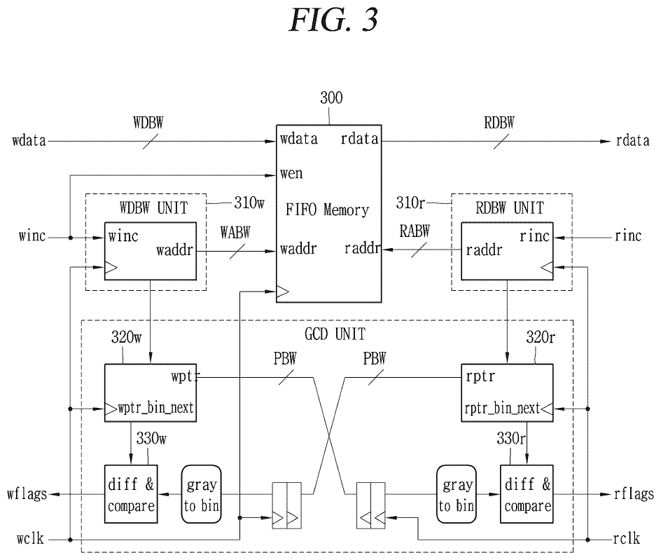

FIG. 3 is an overall block diagram illustrating an asymmetric asynchronous FIFO memory device according to the present disclosure.

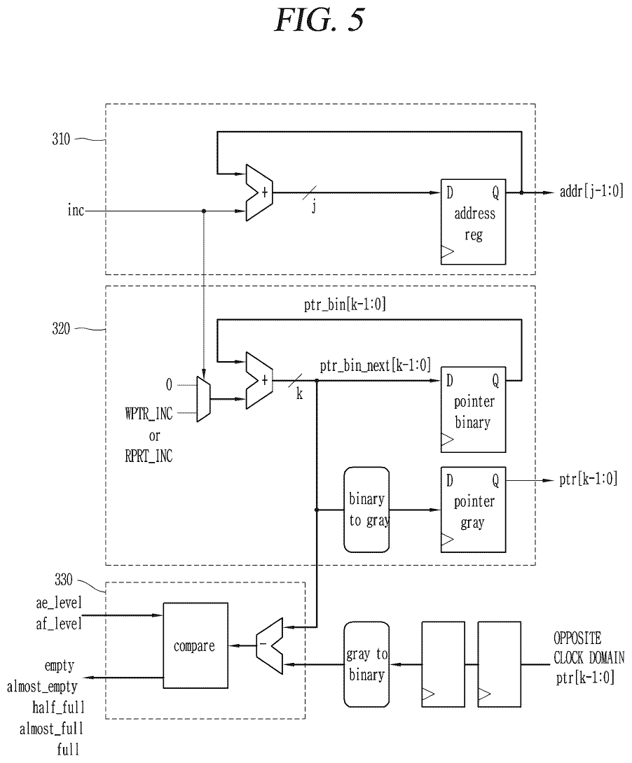

A memory device according to one embodiment of the present disclosure may include a First-In, First-Out (FIFO) memory 300 configured such that data is input and output, an address counter 310 (see FIG. 5) in unit of read and write data widths for controlling read and write addresses of the FIFO memory 300, an address pointer generator 320 (see FIG. 5) capable of comparing a read clock domain and a write clock domain to check the status of the FIFO memory 300, and a flag generator 330 (see FIG. 5) to output the status of the FIFO memory based on a comparison of address pointers generated by the address pointer generator 320.

The address pointer generator 320 may be driven in a unit of the greatest common divisor of the read data width and the write data width to compare the read clock domain and the write clock domain for checking the status of the FIFO memory 300.

In the FIFO memory 300, the read data width and the write data width may be processed differently.

That is, the memory device according to the present disclosure may be an asynchronous FIFO memory device having different data widths for writing and reading, and may include an asymmetric memory 300 having different write and read data widths, an address counter 310 that controls addresses of the FIFO memory, an address pointer generator 320 to compare clock domains for checking a memory status, and a flag generator 330.

FIG. 3 is an overall schematic diagram illustrating an asymmetric asynchronous FIFO memory device according to the present disclosure. Since write and read data widths are different but the units of the address pointers are the same, the memory address pointers between two clock domains can be compared.

Abbreviations and definitions shown in the drawings refer to the following.
WDBW: Write Data Bit Width
RDBW: Read Data Bit Width
GCD: Greatest Common Divisor, the greatest common divisor of write and read data widths
LCM: Least Common Multiple, the least common multiple of write and read data widths
WADP: Write Address Depth
RADP: Read Address Depth
MEMB: Total Memory Bits
wae_level: Write Almost Empty Level Control
waf_level: Write Almost Full Level Control
rae_level: Read Almost Empty Level Control
raf_level: Read Almost Full Level Control
MEMB=WDBW*WADP=LCM*N, (N>1, integer)
GMEMB=MEMB/GCD
WPTR_INC=WDBW/GCD
RPTR_INC=RDBW/GCD
wdiff=wptr_bin_next−gray2bin(rptr_sync2)
wempty=wdiff==0
walmost_empty=wdiff<=wae_level*WPTR_INC
whalf_full=wdiff>=(GMEMB+1)/2
walmost_full=wdiff>=GMEMB-waf_level*WPTR_INC
wfull=wdiff>=GMEMB
rdiff=gray2bin(wptr_sync2)−rptr_bin_next
rempty=rdiff==0
ralmost_empty=rdiff<=rae_level*RPTR_INC
rhalf_full=rdiff>=(GMEMB+1)/2
ralmost_full=rdiff>=GMEMB-raf_level*RPTR_INC
rfull=rdiff>=GMEMB

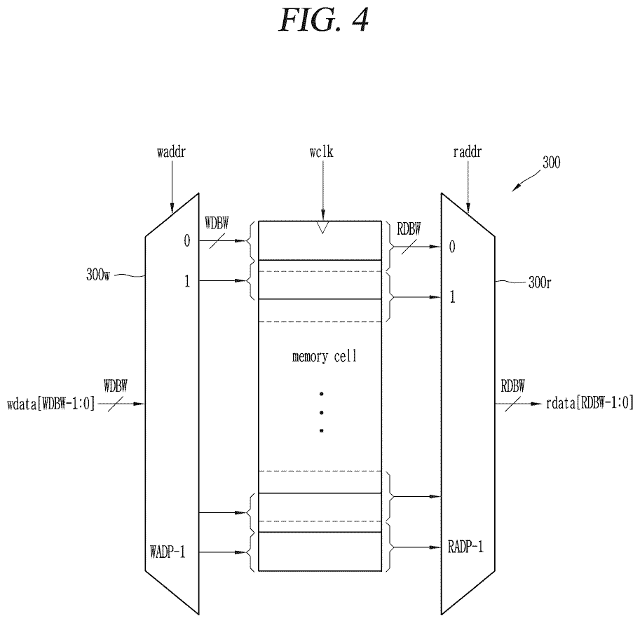

FIG. 4 is a block diagram of an asymmetric memory with different write and read data widths.

Referring to FIG. 4, a First-In, First-Out (FIFO) memory 300 according to the present disclosure may include a first clock domain in which write data is processed and a second clock domain in which read data is processed.

The FIFO memory 300 according to the present disclosure is an asymmetric FIFO memory in which a write data width WDBW processed in the first clock domain and a read data width RDBW processed in the second clock domain are different from each other.

The FIFO memory 300 may include a write address decoder 300w and a read address decoder 300r.

The write address decoder 300w may have the write data width WDBW, and the read address decoder 300r may have the read data width RDBW.

FIG. 5 is a block diagram illustrating an address counter in unit of each data width, an address pointer in unit of greatest common divisor of write and read data widths, and a comparator.

The address pointer generator according to the present disclosure may form address pointers in unit of the greatest common divisor of a write data width and a read data width to compare address pointers between the first clock domain where write data is processed and the second clock domain where read data is processed.

Specifically, the address counter 310 may count the data width of each of the first clock domain where the write data is processed and the second clock domain where the read data is processed, which are included in the FIFO memory.

The address pointer generator 320 may generate address pointers in the unit of the greatest common divisor of the write data width and the read data width to compare the address pointers between the first clock domain and the second clock domain.

The flag generator 330 may include a comparator compare that compares the address pointers of the first clock domain with the address pointer of the second clock domain.

The address pointer generator 320 may be configured to increase a write address pointer by a value WPTR_INC, which is obtained by dividing the write data width by the greatest common divisor of the write data width and the read data width, and to increase a read address pointer by a value RPRT_INC, which is obtained by dividing the read data width by the greatest common divisor.

That is, an address pointer generator according to the present disclosure may include a write and read address counter 310 of an asynchronous FIFO memory driven by data widths of a write domain and a read domain, a generator 320 that configures address pointers in unit of greatest common divisor of write and read data widths for comparison of address pointers between the two domains, and a comparator 330.

A write address pointer may increase in WPTR_INC unit, and the read address pointer may increase in RPTR_INC unit.

WPTR_INC and RPTR_INC are values obtained by dividing each data width by the greatest common divisor of the two data widths.

The flag generator may output a flag regarding the status of the FIFO memory based on a result of comparing the address pointer of the first clock domain with the address pointer of the second clock domain in the comparator.

The flag may include empty, almost_empty, half_full, almost_full, full, etc., and may include information indicating the status of the FIFO memory 300. The flag may be added or changed depending on user settings.

In the memory device according to the present disclosure, the address counter 310 is driven in the unit of write data width and read data width, and the generator 320, the comparator, and the flag generator 330 are driven in the unit of the greatest common divisor of the write data width and the read data width.

The write data width and read data width may be changed depending on settings.

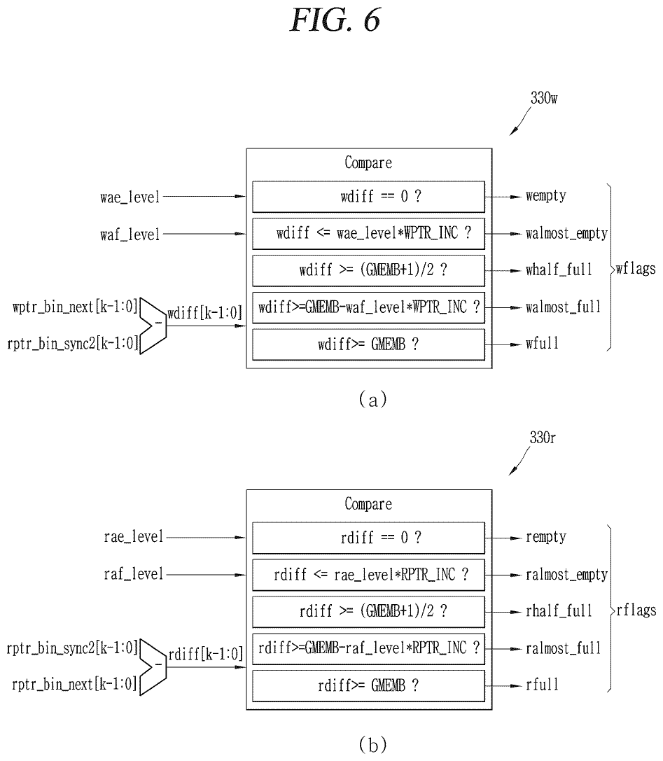

FIG. 6 is a block diagram of status flag calculation using comparison of address pointers in unit of greatest common divisor of write and read data widths.

(a) of FIG. 6 is a block diagram of calculation in a flag generator of a write part, and (b) of FIG. 6 is a block diagram of calculation in a flag generator of a read part.

The flag generators 330w and 330r may generate flags for empty, almost_empty, half_full, almost_full, and full by comparing the address pointers in the corresponding clock domains.

The steps of a method or algorithm described in connection with an embodiment of the present disclosure may be implemented directly in hardware, implemented as a software module executed by hardware, or implemented by a combination thereof. The software module may reside in a random access memory (RAM), a read only memory (ROM), an erasable programmable ROM (EPROM), an electrically erasable programmable ROM (EEPROM), a flash memory, a hard disk, a removable disk, a CD-ROM, or any other type of computer-readable storage medium well known in the art to which the present disclosure pertains.

Although the embodiment of the present disclosure has been described with reference to the attached drawings, those skilled in the art will appreciate that the present disclosure may be implemented in other specific forms without changing the technical idea or essential features thereof. Therefore, it should be understood that the embodiments described above are exemplary in all respects and not restrictive.

1. A memory device comprising:
a First-in, First-out (FIFO) memory where data is input and output;
an address counter that controls writing and reading of the FIFO memory;
an address pointer generator that is capable of comparing a write clock domain and a read clock domain for checking a status of the FIFO memory; and
a flag generator that outputs the status of the FIFO memory based on a comparison of address pointers generated by the address pointer generator,
wherein a write data width and a read data width are differently processed in the FIFO memory.

2. The memory device of claim 1, wherein the FIFO memory comprises a first clock domain in which write data is processed and a second clock domain in which read data is processed, and
is an asymmetric FIFO memory in which the write data width processed in the first clock domain and the read data width processed in the second clock domain are different from each other.

3. The memory device of claim 1, wherein the FIFO memory comprises a write address decoder and a read address decoder,
the write address decoder is configured with the write data width, and
the read address decoder is configured with the read data width.

4. The memory device of claim 1, wherein the address pointer generator generates the address pointers in unit of greatest common divisor of the write data width and the read data width to compare address pointers between a first clock domain where write data is processed and a second clock domain where read data is processed.

5. The memory device of claim 1, wherein the address counter counts a data width of each of a first clock domain where write data is processed and a second clock domain where read data is processed, which are included in the FIFO memory,
the address pointer generator generates the address pointers in unit of greatest common divisor of the write data width and the read data width to compare the address pointers between the first clock domain and the second clock domain, and
the flag generator comprises a comparator that compares the address pointer of the first clock domain with the address pointer of the second clock domain.

6. The memory device of claim 5, wherein the address pointer generator increases a write address pointer by a value obtained by dividing the write data width by the greatest common divisor of the write data width and the read data width, and
increases a read address pointer by a value obtained by dividing the read data width by the greatest common divisor.

7. The memory device of claim 5, wherein the flag generator outputs a flag regarding the status of the FIFO memory based on a result of comparing the address pointer of the first clock domain with the address pointer of the second clock domain in the comparator.

8. The memory device of claim 5, wherein the address counter is driven in unit of the write data width and the read data width, and
the address pointer generator and the flag generator are driven in the unit of the greatest common divisor of the write data width and the read data width.

9. The memory device of claim 1, wherein the write data width and the read data width are changed depending on settings.
